(19) United States
(12) Patent Application Publication
(10) Pub. No.: US 2021/0195758 A1
(43) Pub. Date: Jun. 24, 2021

(54) RESIN-SEALED IN-VEHICLE ELECTRONIC CONTROL DEVICE

(71) Applicant: Hitachi Automotive Systems, Ltd., Hitachinaka-shi, Ibaraki (JP)

(72) Inventors: Kazuhiro SUZUKI, Tokyo (JP); Yoshio KAWAI, Tokyo (JP); Toshiaki ISHII, Tokyo (JP); Shota EZAKI, Tokyo (JP)

(73) Assignee: Hitachi Automotive Systems, Ltd., Hitachinaka-shi, Ibaraki (JP)

(21) Appl. No.: 17/057,322

(22) PCT Filed: Jun. 11, 2019
(86) PCT No.: PCT/JP2019/023017

§ 371 Date: Nov. 20, 2020

(30) Foreign Application Priority Data
Jul. 5, 2018 (JP) 2018-128113

(51) Int. Cl. H05K 3/28; H01R 12/52

(52) U.S. Cl. CPC H05K 3/284; H05K 2203/1147; H01R 12/52; H05K 3/285

(57) ABSTRACT

A resin-sealed in-vehicle electronic control device in the present disclosure is a resin-sealed in-vehicle electronic control device including a circuit board on which an electronic component is mounted, a connector housing that electrically connects the circuit board to an external terminal, and a sealing resin fixing the connector housing to the circuit board. The connector housing has a through hole allowing communication between a second end surface located opposite to a first end surface on which the external terminal is mounted and a side surface of the connector housing adjoining the second end surface, and the sealing resin is continuous to fill at least the inside of the through hole and cover a part of an outer periphery of the connector housing and at least a part of an outer periphery of the circuit board.

### TECHNICAL FIELD

The present invention relates to a resin-sealed in-vehicle electronic control device.

### BACKGROUND ART

Concerning an electronic control unit mounted in a passenger compartment of a vehicle, such as an engine control unit or an automatic transmission control unit, there has been a change in installation location such that the electronic control unit is installed in an engine room, on an engine, in a transmission, or the like, and the electronic control unit itself has been downsized. Accordingly, a heat generation rate per unit volume increases, resulting in exposure to higher temperature environments, and demands for vibration resistance and impact resistance increase.

To meet such demands, there is disclosed, for example, a technology in which a connector housing connecting a circuit board on which an electronic component is mounted and an external terminal is integrally sealed with a resin (see, for example, PTL 1). According to such a technology, since the circuit board and the like are sealed with the resin, there is an advantageous effect in heat resistance, vibration resistance and impact resistance.

### CITATION LIST

### Patent Literature

PTL 1: WO 2005/004563 A

### SUMMARY OF INVENTION

### Technical Problem

However, in the related art as described above, a thermal expansion of a resin used for a connector housing is greatly different from that for a sealing resin. As a result, there is concern that the connector housing and the sealing resin may be peeled off at an interface therebetween at the time of cooling after molding and separated from each other according to the progression of the peeling-off.

Based on the above-described circumstances, an object of the present invention is to provide a resin-sealed in-vehicle electronic control device having a simple configuration for securely fixing the connector housing and the sealing resin.

### Solution to Problem

In order to solve the above problems, a resin-sealed in-vehicle electronic control device according to a preferred mode of the present invention includes: a circuit board on which an electronic component is mounted; a connector housing that electrically connects the circuit board to an external terminal; and a sealing resin fixing the connector housing to the circuit board. The connector housing has a through hole and/or a cut-out portion allowing communication between a second end surface located opposite to a first end surface on which the external terminal is mounted and a side surface of the connector housing adjoining the second end surface. The sealing resin is continuous to fill at least the inside of the through hole and/or the cut-out portion and cover a part of an outer periphery of the connector housing and at least a part of an outer periphery of the circuit board.

In the present specification, the term “external terminal” refers to a terminal of a device other than the resin-sealed in-vehicle electronic control device to be electrically connected to a metal terminal provided in connector housing. In addition, the term “substantially shape” is a concept including, for example, a substantially “T” shape, in which the substantially “L” shape is partially included.

### Advantageous Effects of Invention

According to the present invention, a resin-sealed in-vehicle electronic control device having a simple configuration for securely fixing a connector housing and a sealing resin can be provided.

### BRIEF DESCRIPTION OF DRAWINGS

FIG. 1 is a schematic cross-sectional view illustrating a first embodiment of the present invention.

FIG. 2 illustrates modified examples of FIG. 1, in which FIG. 2(a) illustrates a first modified example and FIG. 2(b) illustrates a second modified example.

FIG. 3 is an enlarged schematic view illustrating a main portion of FIG. 1, in which FIG. 3(a) is a projection view of a connector housing and FIG. 3(b) illustrates a connected state between the connector housing and a sealing resin.

FIG. 4 is a schematic cross-sectional view illustrating an example of a method of forming a resin-sealed in-vehicle electronic control device of FIG. 1, in which FIG. 4(a) illustrates a state before filling the sealing resin, FIG. 4(b) illustrates a state after filling the sealing resin, and FIG. 4(c) illustrates a state after mold releasing.

FIG. 5 is an enlarged schematic view illustrating a main portion in a second embodiment of the present invention, in which FIG. 5(a) is a projection view of a connector housing and FIG. 5(b) illustrates a connected state between the connector housing and a sealing resin.

FIG. 6 is an enlarged schematic view illustrating a main portion in a third embodiment of the present invention, in which FIG. 6(a) is a projection view of a connector housing and FIG. 6(b) illustrates a connected state between the connector housing and a sealing resin.

FIG. 7 is an enlarged schematic view illustrating a main portion in a modified example of FIG. 6, in which FIG. 7(a) is a projection view of a connector housing and FIG. 7(b) illustrates a connected state between the connector housing and a sealing resin.

FIG. 8 is an enlarged schematic view illustrating a main portion in a fourth embodiment of the present invention, in which FIG. 8(a) is a projection view of a connector housing and FIG. 8(b) illustrates a connected state between the connector housing and a sealing resin.

FIG. 9 is a schematic cross-sectional view illustrating a fifth embodiment of the present invention.

### DESCRIPTION OF EMBODIMENTS

The resin-sealed in-vehicle electronic control device is a resin-sealed in-vehicle electronic control device including a circuit board on which an electronic component is mounted, a connector housing that electrically connects the circuit board to an external terminal, and a sealing resin fixing the connector housing to the circuit board. The connector housing has a through hole and/or a cut-out portion allowing communication between a second end surface located opposite to a first end surface on which the external terminal is mounted and a side surface of the connector housing adjoining the second end surface. The sealing resin is continuous to fill at least the inside of the through hole and/or the cut-out portion and cover a part of an outer periphery of the connector housing and at least a part of an outer periphery of the circuit board.

Hereinafter, first to fifth embodiments of the present invention will be described with reference to the drawings, but the present invention is not limited only to the embodiments described based on the drawings.

### First Embodiment

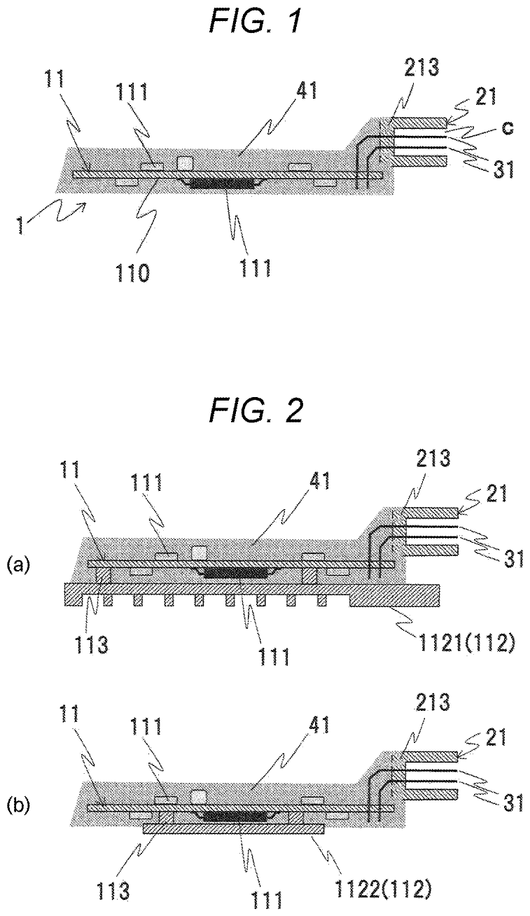

FIG. 1 is a schematic cross-sectional view illustrating a first embodiment of the present invention. As illustrated in FIG. 1, the resin-sealed in-vehicle electronic control device 1 mainly includes a circuit board 11, a connector housing 21, and a sealing resin 41.

The circuit board 11 has an electronic component mounted thereon. For example, as illustrated in FIG. 1, on the circuit board 11, electronic components 111 including heat generating electronic components, such as a capacitor and a resistor, are joined to both surfaces of a substrate 110 by soldering or the like, and metal terminals 31 are provided for connection to external terminals that are not illustrated. In addition, as illustrated in FIGS. 2(a) and 2(b), a metal base 112 for heat dissipation may be mounted on the circuit board 11 via a thermally conductive spacer 113. As the metal base 112, a metal base 1121 having heat dissipation fins is illustrated in FIG. 2(a), and a flat metal base 1122 is illustrated in FIG. 2(b).

The connector housing 21 electrically connects the circuit board 11 to external terminals. As illustrated in FIG. 1, the connector housing 21 has the metal terminals 31 in an opening c thereof, and the above-described circuit board 11 is connected to the metal terminals 31. As the connector housing 21, for example, a surface-mount type connector housing (not shown) or the like can be adopted, as well as the connector housing 21 that is in a pin insertion type as illustrated in FIGS. 2(a) and 2(b).

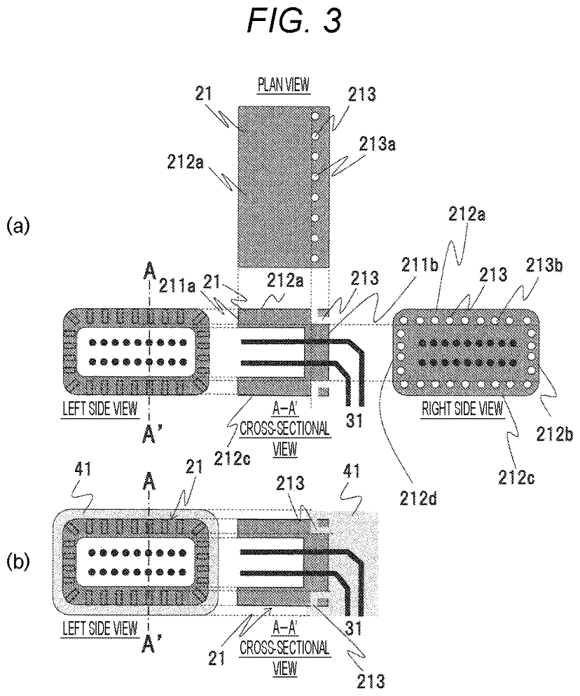

The connector housing 21 of the resin-sealed in-vehicle electronic control device 1 has a through hole 213 in a substantially “L” shape allowing communication between a second end surface located opposite to a first end surface on which the external terminals are mounted and a side surface of the connector housing adjoining the second end surface. As the through hole 213, for example, as illustrated in FIG. 3(a), it can be specifically adopted that each of a plurality of holes 213a and a respective one of a plurality of holes 213b communicate with each other, the holes 213a extending from each of first to fourth side surfaces 212a to 212d toward an opposite side surface thereof in parallel with a second end surface 211b while being opened in each of the first to fourth side surfaces 212a to 212d, and the holes 213b extending from the second end surface 211b toward a first end surface 211a in parallel with each of the first to fourth side surfaces 212a to 212d while being opened in the second end surface 211b.

Here, the connector housing 21 and the sealing resin are estimated to have a shrinkage of no greater than about 1 mm. Accordingly, the through hole 213 preferably has a size of 1 mm or more in both width and height (depth). This value is clearly different from a surface roughness size of the connector housing 21, i.e. several μm to several tens of μm.

The through holes 213 in the connector housing 21 are preferably arranged to be symmetrical vertically and horizontally when viewed from above the second end surface 211b (see a right side view in FIG. 3(a)). Thus, a stress generated in each through hole 213 can be balanced overall, and the shape can be stably maintained for a long period of time.

As a method of forming the through holes 213 in the substantially “L” shape, for example, it can be adopted that when the connector housing 21 is formed by a halved mold or the like, movable pins moving in conjunction with the mold are arranged on the mold in advance to correspond to the respective through holes (e.g. two movable pins/through hole for the through holes in the present embodiment), and the movable pins are pulled out from the respective holes 213a and 213b of the connector housing 21 immediately before releasing the mold.

A material for forming the connector housing 21 is not particularly limited, but the connector housing 21 is preferably formed of a material having flexibility and heat resistance to facilitate production and allow deformation when the external terminals are connected to the connector housing 21. Examples of preferable materials for forming the connector housing 21 include thermoplastic resins such as polybutylene terephthalate (PBT), nylon 6,6 (PA66), and polyphenylene sulfide (PPS).

The sealing resin 41 is a member fixing the connector housing 21 to the circuit board 11. The sealing resin 41 is continuous to fill at least the inside of the through holes and cover a part of an outer periphery of the connector housing and at least a part of an outer periphery of the circuit board. In the present embodiment, as illustrated in FIG. 3(b), the sealing resin 41 is formed as a single member that is continuous to fill the inside of all of the through holes 213 in the substantially “L” shape and cover a part of the outer periphery of the connector housing 21 and the entire outer periphery of the circuit board (not shown), thereby fixing the connector housing 21 to the circuit board 11.

A material for forming the sealing resin 41 is not particularly limited as long as the effect of the present invention is not impaired thereby, but preferably has heat resistance, high thermal conductivity, vibration resistance and impact resistance to promote heat dissipation from the electronic components 111 and reduce vibration or impact exerted on the circuit board 11 and the connector housing 21. Examples of preferable materials for forming the sealing resin 41 include thermosetting resins such as an epoxy resin, a phenol resin, an unsaturated polyester resin, a silicone resin, an acrylic resin, and a methacrylic resin.

Preferably, the connector housing 21 described above has a larger linear expansion coefficient than the sealing resin 41. For example, by using an epoxy resin as a material for the sealing resin 41 and polybutylene terephthalate or nylon 66 as a material for the connector housing, the linear expansion coefficient (about 20×10⁻⁶ to 120×10⁻⁶(1/K)) of the connector housing 21 can be set to be larger than the linear expansion coefficient (about 15×10⁻⁶(1/K)) of the sealing resin 41. This makes it easier for the connector housing 21 to shrink than for the sealing resin 41 at the time of cooling the sealing resin 41 when the resin-sealed in-vehicle electronic control device 1 is manufactured, and thus, the connector housing 21 and the sealing resin 41 can further tightly adhere to each other in a firm way.

Next, a method of forming the resin-sealed in-vehicle electronic control device 1 will be described.

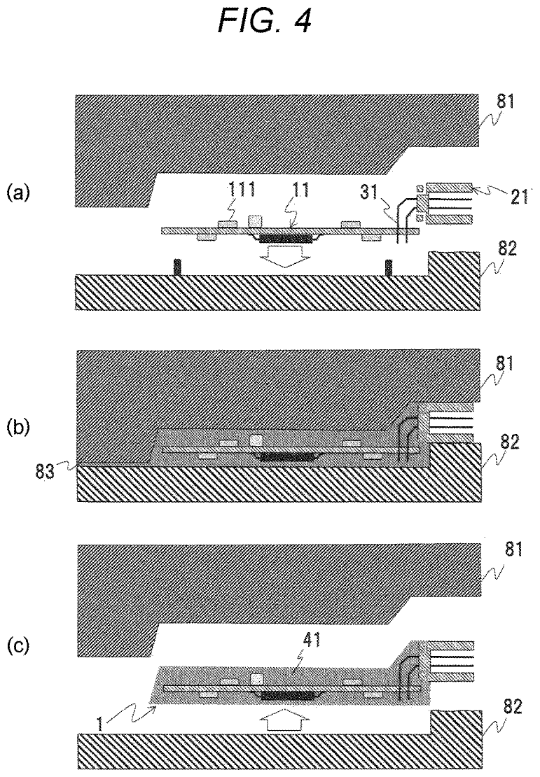

FIG. 4 is a schematic cross-sectional view illustrating an example of a method of forming the resin-sealed in-vehicle electronic control device 1 of FIG. 1. For the resin-sealed in-vehicle electronic control device 1, first of all, the circuit board 11 to which the electronic components 111 are joined by soldering is used, and the metal terminals 31 of the connector housing 21 are connected to the circuit board 11 by soldering.

Next, after the circuit board 11 to which the connector housing 21 is joined as described above is set between molds 81 and 82 (see FIG. 4(a)), the molds 81 and 82 are closed and the sealing resin melted in advance is injected into a space between the molds 81 and 82 through a resin injection gate 83 (see FIG. 4(b)). Subsequently, the sealing resin 41 is cured, and then the molds 81 and 82 are opened to take the molded product out (see FIG. 4(c)), thereby obtaining the resin-sealed in-vehicle electronic control device 1 covered with the sealing resin 41.

A thickness of the sealing resin 41 covering the outer periphery of the connector housing 21 is not particularly limited as long as the effect of the present invention is not impaired thereby. For example, the thickness of the sealing resin 41 from a surface of the connector housing can be almost the same as a depth of the through holes.

As described above, since the resin-sealed in-vehicle electronic control device 1 has the above-described configuration, it is possible to securely fix the connector housing 21 and the sealing resin 41 to each other based on the simple configuration, without adding a member. As a result, the cost of the resin-sealed in-vehicle electronic control device 1 can be reduced.

In addition, in the present embodiment, the sealing resin 41 flowing into the through hole 213 serves as one restraint point, and the metal terminal 31 penetrating through the connector housing 21 and located in the sealing resin 41 serves as another restraint point. Thus, when the resin of the connector housing shrinks between these restraint points, a tensile stress is generated in the connector housing 21 and a shrinkage stress is generated in the sealing resin 41, and these two stresses are balanced, thereby more firmly connecting the connector housing 21 and the sealing resin 41 to each other.

### Second Embodiment

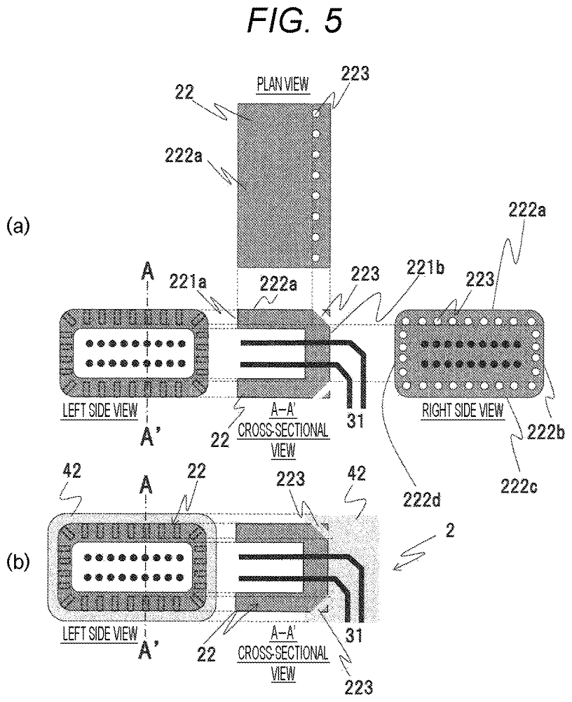

FIG. 5 is an enlarged schematic view illustrating a main portion in a second embodiment of the present invention. The resin-sealed in-vehicle electronic control device 2 mainly includes a circuit board 11 (not shown), a connector housing 22, and a sealing resin 42. The resin-sealed in-vehicle electronic control device 2 is different from that in the first embodiment in configurations of the connector housing 22 and the sealing resin 42. A configuration of the circuit board 11, configurations other than shapes of through holes 223 of the connector housing 22 and the sealing resin 42, and a method of forming the resin-sealed in-vehicle electronic control device 2 are the same as those in the first embodiment. Thus, the same elements are denoted by the same reference signs, and the description of the first embodiment is incorporated by reference therefor.

The connector housing 22 electrically connects the circuit board 11 to external terminals. The connector housing 22 of the resin-sealed in-vehicle electronic control device 2 has through holes 223 in a substantially straight-line shape allowing communication between a second end surface and a side surface of the connector housing adjoining the second end surface. As the through hole 223, for example, it can specifically be adopted, as illustrated in FIG. 5(a), that each of first to fourth side surfaces 222a to 222d has openings therein and a second end surface 221b has a plurality of openings therein, and each of the openings in the first to fourth side surfaces 222a to 222d communicates with (passes through) a respective one of the openings in the second end surface 221b in a straight line.

As a method of forming the through holes 223 in the substantially straight-line shape, for example, it can be adopted that when the connector housing 22 is formed by a mold or the like, movable pins are arranged on the mold in advance to correspond to the respective through holes 223 (e.g. one movable pin/through hole for the through holes in the present embodiment), and the movable pins are pulled out from the respective holes of the connector housing 22 immediately before releasing the mold.

The sealing resin 42 is a member fixing the connector housing 22 to the circuit board 11. The sealing resin 42 is continuous to fill at least the inside of the through holes and cover a part of an outer periphery of the connector housing and at least a part of an outer periphery of the circuit board. In the present embodiment, as illustrated in FIG. 5(b), the sealing resin 42 is formed as a single member that is continuous to fill the inside of all of the through holes 223 in the substantially straight-line shape and cover a part of the outer periphery of the connector housing 22 and the entire outer periphery of the circuit board 11 (not shown), thereby fixing the connector housing 22 to the circuit board 11.

As described above, since the resin-sealed in-vehicle electronic control device 2 has the above-described configuration, it is possible to securely fix the connector housing 22 and the sealing resin 42 to each other based on the simple configuration, without adding a member. Furthermore, since the through hole 223 is in the substantially straight-line shape, it is less likely that the flow of the resin spreads towards the movable pins at the time of forming the connector housing 22. Thus, the connector housing 22 can be expected to be molded more accurately.

### Third Embodiment

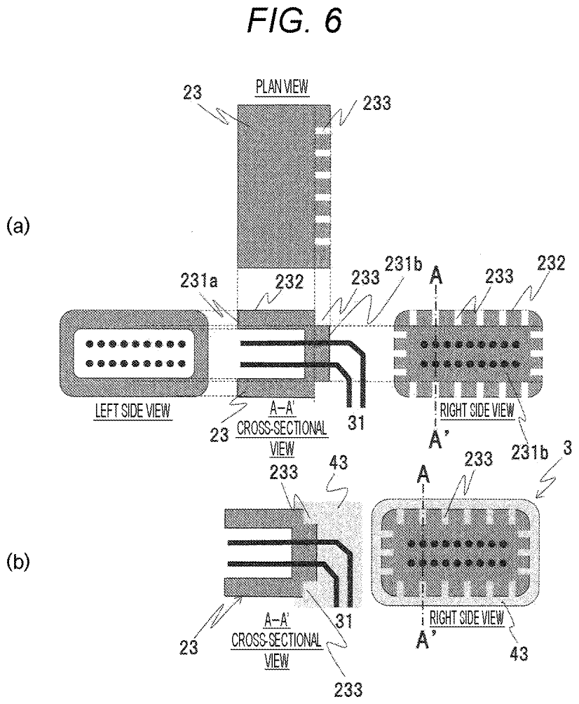

FIG. 6 is an enlarged schematic view illustrating a main portion in a third embodiment of the present invention. As illustrated in FIG. 6, the resin-sealed in-vehicle electronic control device 3 mainly includes a circuit board (not shown), a connector housing 23, and a sealing resin 43. The resin-sealed in-vehicle electronic control device is different from that in the first embodiment in configurations of the connector housing 23 and the sealing resin 43. A configuration of the circuit board 11, configurations other than shapes of cut-out portions 233 of the connector housing 23 and the sealing resin 43, and a method of forming the resin-sealed in-vehicle electronic control device 3 are the same as those in the first embodiment. Thus, the same elements are denoted by the same reference signs, and the description of the first embodiment is incorporated by reference therefor.

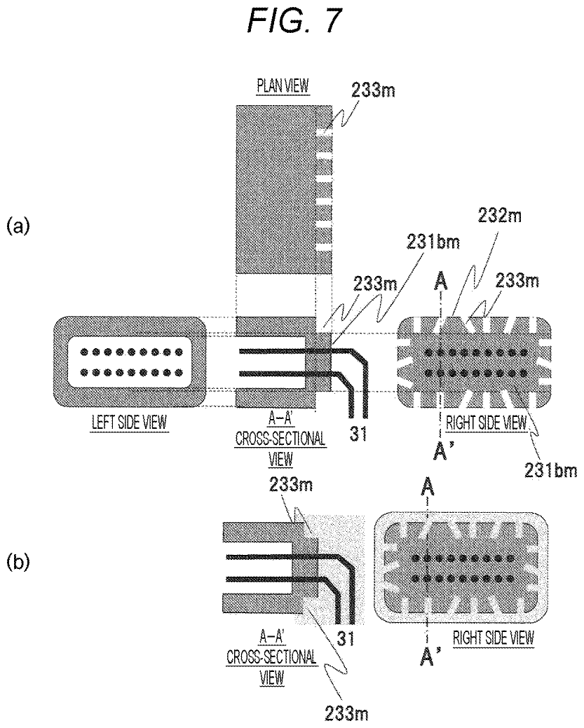

The connector housing 23 electrically connects the circuit board 11 to external terminals. The connector housing 23 has cut-out portions 233 allowing communication between a second end surface 231b located opposite to a first end surface 231a on which the external terminals are mounted and a side surface 232 of the connector housing 23 adjoining the second end surface 231b. As a shape of the cut-out portion 233, for example, it can specifically be adopted that each cut-out portion 233 is in a rectangular shape to be elongated in such a direction as to become deeper from the side surface 232 to which the cut-out portion 233 belongs, when viewed from above the second end surface 231b. The direction in which the cut-out portion 233 becomes deeper can be perpendicular to the side surface 232 (see FIG. 6(a)), when viewed from above the second end surface 231b (see a right side view in FIG. 6(a)). Alternatively, a direction in which at least one of a plurality of cut-out portions 233m belonging to a same side surface 232m with respect to a second end surface 231bm becomes deeper can be different from that in which another cut-out portion 233m of the plurality of cut-out portions 233m becomes deeper (see the cut-out portions 233m in FIG. 7(a)), when viewed from above the second end surface 231bm (see a right side view in FIG. 7(a)). Among them, the cut-out portions 233m illustrated in FIG. 7(a) are more preferable in that the sealing resin and the connector housing can be more securely fixed to each other.

In addition, the cut-out portions 233 in the present embodiment can be formed, for example, by arranging projections (not shown) corresponding to the respective cut-out portions 233 on a mold for forming the connector housing 23.

The sealing resin 43 is a member fixing the connector housing 23 to the circuit board 11. The sealing resin 43 is continuous to fill at least the inside of the cut-out portions and cover a part of an outer periphery of the connector housing and at least a part of an outer periphery of the circuit board. In the present embodiment, as illustrated in FIG. 6(b), the sealing resin 43 is formed as a single member that is continuous to fill the inside of all of the cut-out portions 233 and cover a part of the outer periphery of the connector housing 23 and the entire outer periphery of the circuit board 11 (not shown), thereby fixing the connector housing 23 to the circuit board 11.

As described above, since the resin-sealed in-vehicle electronic control device 3 has the above-described configuration, it is possible to securely fix the connector housing 23 and the sealing resin 43 to each other based on the simple configuration, without adding a member.

### Fourth Embodiment

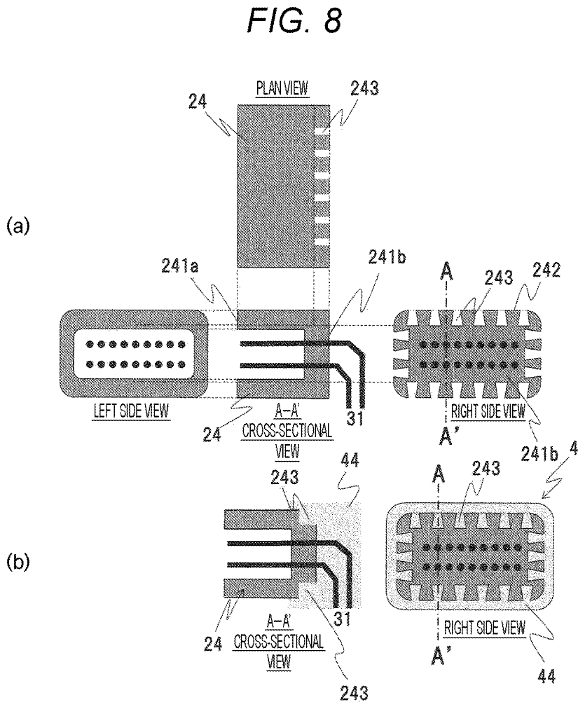

FIG. 8 is an enlarged schematic view illustrating a main portion in a fourth embodiment of the present invention. The resin-sealed in-vehicle electronic control device 4 mainly includes a circuit board 11 (not shown), a connector housing 24, and a sealing resin 44. The resin-sealed in-vehicle electronic control device 4 is different from that in the first embodiment in configurations of the connector housing 24 and the sealing resin 44. A configuration of the circuit board 11, configurations other than shapes of cut-out portions 243 of the connector housing 24 and the sealing resin 44, and a method of forming the resin-sealed in-vehicle electronic control device 4 are the same as those in the first embodiment. Thus, the same elements are denoted by the same reference signs, and the description of the first embodiment is incorporated by reference therefor.

The connector housing 24 electrically connects the circuit board 11 to external terminals. The connector housing 24 has cut-out portions 243 allowing communication between a second end surface 241b located opposite to a first end surface 241a on which the external terminals are mounted and a side surface 242 of the connector housing 24 adjoining the second end surface 241b. Concerning a shape of the cut-out portion 243, each of the cut-out portions 243 is formed to have a shape in which a width of the cut-out portion 243 on a side surface to which the cut-out portion 243 belongs is smaller than a maximum width in the cut-out portion 243, when viewed from above the second end surface 241b (see a right side view in FIG. 8(a)). As the shape of the cut-out portion 243, for example, it can specifically be adopted, as illustrated in FIG. 8(a), that the cut-out portion 243 has a width that is gradually larger as being farther away from the side surface 242 to which the cut-out portion 243 belongs (a wedge shape), when viewed from above the second end surface 241b.

In addition, the cut-out portions 243 in the present embodiment can be formed, for example, by arranging projections (not shown) corresponding to the respective cut-out portions 243 on a mold for forming the connector housing 24, injecting a resin into the mold, and then pulling out the mold in a direction perpendicular to the second end surface 241b.

The sealing resin 44 is a member fixing the connector housing 24 to the circuit board 11. The sealing resin 44 is continuous to fill at least the inside of the cut-out portions 243 and cover a part of an outer periphery of the connector housing 24 and at least a part of an outer periphery of the circuit board 11. In the present embodiment, as illustrated in FIG. 8(b), the sealing resin 44 is formed as a single member that is continuous to fill the inside of all of the cut-out portions 243 and cover a part of the outer periphery of the connector housing 24 and the entire outer periphery of the circuit board 11 (not shown), thereby fixing the connector housing 24 to the circuit board 11.

As described above, since the resin-sealed in-vehicle electronic control device 4 has the above-described configuration, it is possible to securely fix the connector housing 24 and the sealing resin 44 to each other based on the simple configuration, without adding a member. Furthermore, since the cut-out portions 243 have the above-described configuration, even if the connector housing 24 shrinks, it is difficult for the sealing resin 44 to escape from the cut-out portions 243, and the restraint points are stably maintained. Thus, the connection between the connector housing 24 and the sealing resin 44 can be firmly maintained.

### Fifth Embodiment

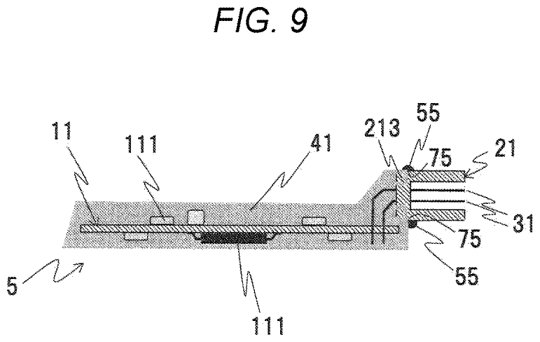

FIG. 9 is a schematic cross-sectional view illustrating a fifth embodiment of the present invention. As illustrated in FIG. 9, the resin-sealed in-vehicle electronic control device 5 mainly includes a circuit board 11, a connector housing 21, a sealing resin 41, and an elastic member 55. The resin-sealed in-vehicle electronic control device 5 is different from that in the first embodiment in that the elastic member 55 is included. Configurations of the circuit board 11, the connector housing 21, and the sealing resin 41, and a method of forming the resin-sealed in-vehicle electronic control device 5 are the same as those in the first embodiment. Thus, the same elements are denoted by the same reference signs, and the description of the first embodiment is incorporated by reference therefor.

The elastic member 55 covers at least a part of an externally exposed portion at a boundary between the connector housing and the sealing resin. Specifically, for example, as illustrated in FIG. 9, the elastic member 55 can be provided to tightly adhere to both the connector housing 21 and the sealing resin 41 and entirely cover an externally facing portion (externally exposed portion 75) of the boundary.

As a material for forming the elastic member 55, a material having excellent adhesion to the connector housing 21 and the sealing resin 41 is preferable. Examples of the elastic member 55 include low elastic members such as silicone rubber.

As described above, since the resin-sealed in-vehicle electronic control device 5 has the above-described configuration, it is possible to securely fix the connector housing 21 and the sealing resin 41 to each other based on the simple configuration, without adding a member. Furthermore, since the boundary is covered by the elastic member 55, it is possible to improve sealability so as to, for example, cause no gap in the boundary and prevent moisture from getting into the inside of the device even if the connector housing 21 and the sealing resin 41 are peeled off. In addition, since the elastic member 55 is included, it is possible to suppress excessive concentration of stress in the through holes 213, for example, when an external terminal is connected to the connector housing 21. As a result, it is possible to prevent the connector housing 21 from being damaged.

The present invention is not limited to the configurations of the above-described embodiments, but is intended to cover all modifications falling within the spirit and scope as defined in the claims.

For example, it has been described in the above-described embodiments that each of the resin-sealed in-vehicle electronic control devices 1 to 5 includes either the through holes 213 or 223 or the cut-out portions 233 or 243, but the resin-sealed in-vehicle electronic control device may include both the through holes and the cut-out portions in a mixed manner.

In addition, it has been described in the fifth embodiment that the elastic member 55 entirely covers the externally facing portion (externally exposed portion 75) at the boundary between the connector housing 21 and the sealing resin 41 in the resin-sealed in-vehicle electronic control device 5, but the elastic member 55 may partially cover the externally facing portion at the boundary in the resin-sealed in-vehicle electronic control device.

### REFERENCE SIGNS LIST

1 to 5 resin-sealed in-vehicle electronic control device
11 circuit board
21 to 24 connector housing
41 to 44 sealing resin
211a to 241a first end surface
211b to 241b second end surface
213, 223 through hole
233, 243 cut-out portion

1. A resin-sealed in-vehicle electronic control device comprising:
a circuit board on which an electronic component is mounted;
a connector housing that electrically connects the circuit board to an external terminal; and
a sealing resin fixing the connector housing to the circuit board,
wherein
the connector housing has a through hole and/or a cut-out portion allowing communication between a second end surface located opposite to a first end surface on which the external terminal is mounted and a side surface of the connector housing adjoining the second end surface, and
the sealing resin is continuous to fill at least the inside of the through hole and/or the cut-out portion and cover a part of an outer periphery of the connector housing and at least a part of an outer periphery of the circuit board.

2. The resin-sealed in-vehicle electronic control device according to claim 1, wherein the connector housing has a linear expansion coefficient larger than that of the sealing resin.

3. The resin-sealed in-vehicle electronic control device according to claim 1, wherein
the through hole and/or the cut-out portion allowing communication between the second end surface and the side surface of the connector housing adjoining the second end surface is a through hole, and
the through hole has a substantially “L” shape or a substantially straight-line shape.

4. The resin-sealed in-vehicle electronic control device according to claim 1, wherein
the through hole and/or the cut-out portion allowing communication between the second end surface and the side surface of the connector housing adjoining the second end surface is a cut-out portion, and
the cut-out portion has a shape in which a width of the cut-out portion on the side surface is smaller than a maximum width in the cut-out portion, when viewed from the second end surface.

5. The resin-sealed in-vehicle electronic control device according to claim 1, further comprising an elastic member covering at least a part of an externally exposed portion at a boundary between the connector housing and the sealing resin.
